(19) United States
(12) Patent Application Publication
(10) Pub. No.: US 2007/0097651 A1
(43) Pub. Date: May 3, 2007

(54) Thermal interface material with multiple size distribution thermally conductive fillers

(75) Inventors: Philip L. Canale, Lowell, MA (US); Garrett L. Clark, Westboro, MA (US)

Correspondence Address: REINHART BOERNER VAN DEUREN S.C.;ATTN: LINDA KASULKE, DOCKET COORDINATOR, 1000 NORTH WATER STREET, SUITE 2100, MILWAUKEE, WI, 53202, US

(73) Assignee: TechFilm, LLC

(21) Appl. No.: 11/591,215

(22) Filed: Nov. 1, 2006

Related U.S. Application Data
(60) Provisional application No. 60/732,062, filed on Nov. 1, 2005.

(51) Int. Cl. H05K 7/20

(52) U.S. Cl. 361/704

(57) ABSTRACT

A thermal interface material including a matrix and a thermally conductive filler. The thermally conductive filler includes first and a second thermally conductive particulate materials having different particle size distribution. A maximum particle size of the thermally conductive filler may be established by excluding particles having a size greater than a predetermined particle size from the thermally conductive filler.

### CROSS-REFERENCE TO RELATED APPLICATION

This application claims priority of U.S. Provisional Patent Application No. 60/732,062, which is entitled “Thermally Conductive Filler and Thermal Interface Material,” and which was filed on Nov. 1, 2005, the entirety of which application is hereby incorporated herein by reference.

### BACKGROUND OF THE INVENTION

### Field of the Invention

The present invention relates generally to thermal interface materials, and more particularly to thermal interface materials having at least two thermally conductive fillers having different size distributions.

Thermal management is an important consideration in the development and production of semiconductors and semiconductor devices or “chips.” The efficient operation of semiconductor devices requires that the junction temperatures of a semiconductor be maintained below a threshold temperature or temperature range. It is therefore necessary to dissipate the heat generated by the semiconductor device. Typically, heat generated by the semiconductor device is transferred from the chip to an integral heat spreader, e.g., a semiconductor package. The heat transferred to the semiconductor package may then be dissipated through the use of a heat sink that is placed into close contact with the semiconductor package.

The efficient dissipation of heat from a semiconductor device depends upon several factors, one of which is efficient thermal coupling between the semiconductor chip and the semiconductor package and a second of which is efficient thermal coupling between the semiconductor package and the heat sink. The surfaces at each of these interfaces are typically microscopically rough and macroscopically non-planar, resulting in poor thermal coupling between the adjacent surfaces at each interface. Thermal interface materials consisting of a thermally conductive filler or fillers and a matrix or binder are often used between adjacent surfaces of a thermal interface in an attempt to reduce the thermal impedance and provide improved thermal coupling.

It is accordingly the primary objective of the present invention that it provide a thermal interface material presenting a particularly low level of thermal impedance. It is another primary objective of the present invention that it provide a thermal interface material having good viscosity characteristics, specifically a viscosity that is sufficiently low to provide good flow properties when the thermal interface material is in use between two surfaces. It is a related objective of the present invention that it use particles of thermally conductive filler of at least two different sizes to simultaneously present both excellent thermal interface properties and a lower viscosity to provide very good flow properties.

It is another objective of the present invention that it be capable of using any of a plurality of different thermally conductive fillers to provide excellent characteristics at a modest cost. It is a related objective of the present invention that it be capable of using multiple different thermally conductive fillers each having different particle sizes. It is a further objective of the present invention that the improved and novel thermally conductive fillers be packaged in a binder system that provides excellent performance characteristics that both augment the favorable characteristics of the thermally conductive filler and provide outstanding phase change characteristics.

The present invention must also provide a thermal interface material of a composition that is stable and will remain so for an extended period of time, maintaining its low thermal impedance and other favorable characteristics throughout the operating lifetime of the electronics with which it is associated. In order to enhance the market appeal of the thermal interface material of the present invention, it should also be relatively inexpensive to manufacture to thereby afford it the broadest possible market. Finally, it is also an objective that all of the aforesaid advantages and objectives of the thermal interface material of the present invention be achieved without incurring any substantial relative disadvantage.

### SUMMARY OF THE INVENTION

The disadvantages and limitations of the background art discussed above are overcome by the present invention. With this invention, a thermal interface material is provided which has a thermally conductive filler including a first particulate material having a first particle size distribution and a second particulate material having a second particle size distribution. Both of the first and second particulate materials are made of materials having good thermal conductivity properties, such as silver, aluminum, copper, boron nitride, aluminum nitride, silver coated copper, silver coated aluminum, copper coated aluminum, and diamond. The first and second particulate materials may both be made of the same material, or of different materials.

The first particulate material has a mean size that is between about four to about twenty times the size of the second particulate material. The larger particle size is used to lower the viscosity, while the smaller particle size is used to increase the level of the level of the thermally conductive filler. Additionally, particles having a size larger than a predetermined size may be excluded from either the first particulate material or from both the first and second particulate materials. While this does raise the viscosity somewhat, it compensates for this by providing a more substantial drop in the thermal impedance. Particles having a size greater than the predetermined size may be excluded by separating the particles having a size greater than the predetermined size from the first particulate material prior to combination with the second particular material. Alternatively, particles having a size greater than the predetermined size may be separated from the filler system after the first particulate material has been combined with the second particulate material.

The thermal interface material of the present invention thus includes the thermally conductive filler comprised of the first particulate material having a first particle size distribution and the second particulate material having the second particle size distribution. The thermally conductive filler also includes a matrix material, such as an oil (a silicone oil, hydrocarbon or mineral oil, or petroleum jelly, and/or mixtures thereof), a binder (such as a hydrocarbon rubber, polymeric and/or oligomeric materials (such as epoxy and acrylate materials), and/or mixtures thereof), a phase change material (such as paraffin waxes, microcrystalline waxes, polymeric waxes, and/or mixtures thereof), a coupling agent (such as titanate coupling agent), and/or an antioxidant. The thermal interface material of the present invention advantageously provides a thin bond line thickness and a high filler content due to the high thermally conductive filler packing density, which in turn provides a high thermal conductivity.

It may therefore be seen that the present invention teaches a thermal interface material presenting a particularly low level of thermal impedance. The thermal interface material of the present invention has good viscosity characteristics, specifically a viscosity that is sufficiently low to provide good flow properties when the thermal interface material is in use between two surfaces. The thermal interface material of the present invention uses particles of thermally conductive filler of at least two different sizes to simultaneously present both excellent thermal interface properties and a lower viscosity to provide very good flow properties.

The thermal interface material of the present invention is capable of using any of a plurality of different thermally conductive fillers to provide excellent characteristics at a modest cost. For example, the thermal interface material of the present invention may use multiple different thermally conductive fillers each having different particle sizes. The improved and novel thermally conductive fillers of the thermal interface material of the present invention are packaged in a binder system that provides excellent performance characteristics that both augment the favorable characteristics of the thermally conductive filler and in some embodiments can provide outstanding phase change characteristics.

The thermal interface material of the present invention is of a composition that is stable and will remain so for an extended period of time, maintaining its low thermal impedance and other favorable characteristics throughout the operating lifetime of the electronics with which it is associated. The thermal interface material of the present invention is relatively inexpensive to manufacture to enhance its market appeal and to thereby afford it the broadest possible market. Finally, all of the aforesaid advantages and objectives of the thermal interface material of the present invention are achieved without incurring any substantial relative disadvantage.

### DESCRIPTION OF THE DRAWINGS

These and other advantages of the present invention are best understood with reference to the drawings, in which:

FIG. 1 is a graph of particle size distribution of a first particulate material used in the thermal interface material of the present invention and particle size distribution of a second particulate material also used in the thermal interface material of the present invention;

FIG. 2 schematically depicts packing of particles of the first and second particulate materials having the particle size distributions illustrated in FIG. 1;

FIG. 3 is a graph of particle size distribution of a first particulate material used in an alternate embodiment thermal interface material of the present invention that has particles greater than a predetermined size excluded and particle size distribution of a second particulate material also used in the alternate embodiment thermal interface material of the present invention; and

FIG. 4 is a graph of thermal impedance versus thickness for a thermal interface.

### DETAILED DESCRIPTION OF THE PREFERRED EMBODIMENT

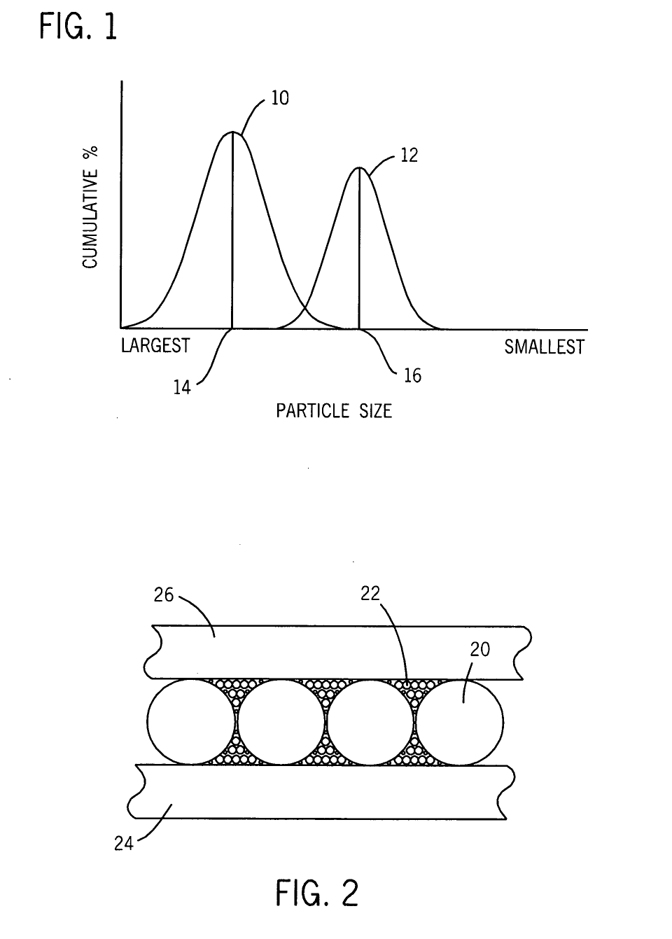

The preferred embodiment of the thermal interface material of the present invention utilizes a thermally conductive filler having at least two particulate materials having different particle size distribution characteristics. Referring to FIG. 1, a thermally conductive filler of a thermal interface material may include a first particulate material having a first size distribution curve that is identified by the reference numeral 10 and a second particulate material having a second size distribution curve that is identified by the reference numeral 12. As used herein, size may refer to particle diameter, largest particle cross-section, average particle cross-section, etc., depending upon the geometry of the particulate materials. In the particulate size distribution curves 10 and 12 shown in FIG. 1, the sizes of the particles of each of the particulate materials may be generally normally distributed, having mean particle sizes 14 and 16, respectively. Particle size distributions other than those shown in FIG. 1 are also contemplated by the present invention, as are the use of normal size distributions. For example, in other embodiments, the first and/or the second particulate material may have a polymodal size distribution, e.g., a bimodal size distribution.

Generally, the mean particle size 14 of the first particulate material may be between about four to about twenty times the mean particle size 16 of the second particulate material. In a first embodiment, the mean particle size 14 of the first particulate material may be on the order of about ten times the mean particle size 16 of the second particulate material. In one such embodiment, the first particulate material may have a mean particle size of approximately 0.8 mils and the second particulate material may have a mean particle size of approximately 0.08 mils. While the size of the respective particulate materials may vary depending upon the specific application contemplated, the mean size of the particles overall may generally range from between about 0.005 mils to about 5 mils.

As shown in FIG. 1, in some embodiments the particle size distribution 10 of the first particulate material and the particle size distribution 12 of the second particulate materials may at least partially overlap at the larger size ranges of the particle size distribution 10 of the first particulate material and the smaller size ranges of the particle size distribution 12 of the second particulate material. In such an embodiment, the first and second particulate materials may together provide a generally bimodal particle size distribution. However, in other embodiments the particle size distributions of the first and the second particulate materials may not overlap. In such embodiments, the thermally conductive filler including the first and the second particulate materials may exhibit two discrete distributions of particle sizes.

The mean particle sizes 14 and 16 and the particle size distributions 10 and 12, respectively, of the first and the second particulate materials, respectively, may facilitate packing of the particulate materials in the thermal interface material of the present invention. Referring now to FIG. 2, a thermal interface material having a thermally conductive filler consisting of a first particulate material 20 and a second particulate material 22 is shown between a first interface surface 24 and a second interface surface 26. The second particulate material 22 generally resides in the interstices of the first particulate material 20.

The respective sizes of the first particulate material 20 and the second particulate material 22 preferably provide a high packing density, and therein a low free volume, of the thermal interface material. While the mean sizes 14 and 16 and the size distributions 10 and 12 of the first and second particulate materials 20 and 22, respectively, may be selected to provide a minimum free volume, in an alternative embodiments a level of free volume may be imparted to the filler system. Furthermore, in other alternative embodiments, the thermally conductive filler of the thermal interface material may include three or more particulate materials each having different particulate size. Consistent with the foregoing, the mean particle size and the particle size distributions of each particulate material used in a given thermally conductive filler may be selected to provide a relatively high packing density.

In addition to the relative mean size of the first and second particulate materials, the volumetric mixing ratio of the first particulate material 20 to the second particulate material 22 may also influence the packing density. For example, increasing the proportion of larger particles, i.e., the first particulate material 20, relative to the smaller particles, i.e., the second particulate material 22, may result in an increase in interstitial volume between the larger particles that is unfilled by the smaller particles. Conversely, increasing the proportion of the smaller particles, i.e., the second particulate material 22, relative to the larger particles, i.e., the first particulate material 20, may overpack the interstitial volume between the larger particles, i.e., the first particulate material 20. overpacking the interstitial volume between the larger particles may force the larger particles apart, and cause separation between the larger particles. Separation between the larger particles may increase the free volume of the filler system.

A desired packing density, or free volume, may, at least in part, be dependent upon the specific end use application being contemplated. The volume ratio of the first particulate material 20 to the second particulate material 22 in the thermal interface material may be varied according to the specific end use application of the thermal interface material and may also be based on specific particle size distributions and particle shapes. In one embodiment, the volume ratio of the first particulate material 20 to the second particulate material 22 may be approximately forty/sixty, thereby providing a relatively high packing density.

Suitable volume ratios of the first particulate material 20 to the second particulate material 22, providing relatively high packing densities, may range from approximately sixty/forty to approximately twenty/eighty. Embodiments of a thermal interface material providing less than maximum packing density are also contemplated by the present invention. The ratio of the first particulate material 20 to the second particulate material 22 may thus be controlled to provide a desired packing density and/or free volume suitable for each specific application. Overall, the first particulate material 20 constitutes between about twenty percent and about seventy percent by volume of the thermal interface material, and the second particulate material 22 constitutes between about ten percent and about seventy percent by volume of the thermal interface material. Optimally, the first particulate material 20 constitutes about 28.35 percent by volume of the thermal interface material, and the second particulate material 22 constitutes about 43.65 percent by volume of the thermal interface material.

According to an alternative embodiment of the present invention, a maximum particle size in the thermal interface material may be established. The maximum particle size may be provided by excluding particles greater than a predetermined size. Excluding particles greater than the chosen predetermined size may include removing any particles having a size greater than the predetermined size from the first particulate material 20 and/or from the thermal interface material including the first and the second particulate materials 20 and 22.

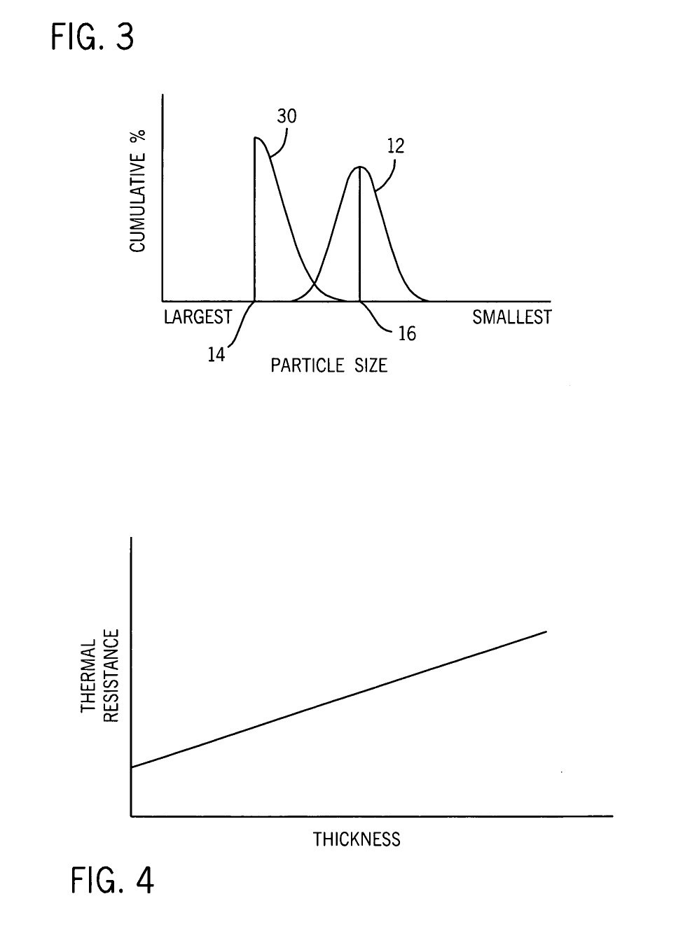

Referring now to FIG. 3, exclusion of particles having a size greater than the chosen predetermined size may produce a modified particle size distribution 30 of the first particulate material. The modified particle size distribution 30 of the first particulate material 20 (shown in FIG. 2) may exhibit a sharp upper size boundary (as shown on the left side of the graph). In the embodiment depicted in FIG. 3, particles having a size greater than the original mean particle size 14 of the first particulate material 20 (in the particulate size distribution 10 shown in FIG. 1) are excluded. Thus, in FIG. 3, the reference numeral 14 does not refer to mean of the particulate size distribution 30, but rather to the mean of the particulate size distribution 10 shown in FIG. 1 as well as the maximum size of the particulate size distribution 30 shown in FIG. 3. This effectively defines the bond line thickness of the thermal interface material of this embodiment as the size of the largest particle in the modified particulate size distribution 30, unlike the particulate size distribution 10 in FIG. 1, where the minimum bond line thickness is established by the size of the largest particle in the particulate size distribution 10.

Alternately, the predetermined size limit may be selected to provide an exclusion limit other than the mean particle size 14. Accordingly, the predetermined size above which particles are excluded from the thermal interface material need not be based on a statistical attribute of the size distribution. Additionally, the predetermined size does not require numerical quantification of a size dimension. Although the particulate size distribution of FIG. 1 potentially has better packing and lower viscosity, the modest increase in viscosity of the particulate size distribution of FIG. 3 is more than outweighed by the effective decreasing of the bond line thickness, thereby resulting in a lower (better performing) thermal impedance.

Exclusion of particles having a size greater than the predetermined size may be achieved using a variety of techniques. Particle exclusion may be carried out by a screening process in which the first particulate material 20 (shown in FIG. 2) has a mean particle size of approximately 0.8 mils and in which particles greater than about the mean particle size are excluded, the screening process using a 635 mesh to achieve the desired separation. Those skilled in the art will realize that the mesh size may be varied to achieve different particle size exclusions. It should be noted that the size exclusion achieved via screening may not be absolute, especially when used for non-spherical particles. For example, a non-spherical particle may have a first cross-sectional area which may pass a given mesh and may further have a second cross-sectional area which may not pass the mesh. Notwithstanding the foregoing, screening will generally provide adequate particle exclusion.

In a first approach to performing this screening, particles having a size greater than the predetermined particle size are excluded from the first particulate material 20 prior to combining the first and second particulate materials 20 and 22 (both shown in FIG. 2) together. For example, the first particulate material 20 may be screened to exclude particles having a size larger than the predetermined particle size. Accordingly, the first particulate material 20 may be processed to provide the modified particle size distribution 30 shown in FIG. 3. Subsequent to this screening operation, the first particulate material 20 having the modified particle size distribution 30 may be combined with the second particulate material 22 to provide the thermally conductive filler. This approach is desirable if the largest particle size in the distribution of the second particulate material 22 is equal to, or smaller than, the predetermined particle size.

In a second approach to performing this screening, particles having a size larger than the predetermined size are excluded after combining the first and second particulate materials together. The first and second particulate materials may be combined using a suitable technique to provide an initial thermally conductive filler. The initial thermally conductive filler may then be processed to remove particles having a size larger than the predetermined size by screening this initial thermally conductive filler. Screening of the initial thermally conductive filler thereby provides the thermally conductive filler as described herein.

Consistent with this second approach, if the second particulate material 22 (shown in FIG. 2) includes a fraction of particles having a size greater than the predetermined particle size, such particles will be excluded. The initial thermally conductive filler in this approach includes both the first particulate material 20 (also shown in FIG. 2) and the second particulate material 22. Therefore, when the initial thermally conductive filler is screened, any particles having a size larger than the predetermined size will be excluded, both from particles of the first particulate material 20 in the first particle size distribution 10 and from particles of the second particulate material 22 in the second particle size distribution 12.

Additionally, in an initial thermally conductive filler including both the first and second particulate materials 20 and 22 (both shown in FIG. 2), the volume ratio of the first and second particulate materials 20 and 22 may take into consideration the quantity and/or fraction of the particles having a size greater than the predetermined size which are to be excluded. Particles having a size greater than the predetermined size may be predominantly and/or entirely present in the first particulate material 20. The relative fraction of the first particulate material 20 may be increased in the initial thermally conductive filler, as compared to the desired final fraction. The increase in the fraction of the first particulate material 20 in the initial thermally conductive filler may provide for the reduction in the quantity and/or fraction of the first particulate material 20 that may result from the exclusion of particles having a size greater than the predetermined particle size.

For example, to provide a thermal interface material having a desired final volume ratio of the first particulate material 20 (shown in FIG. 2) to the second particulate material 22 (also shown in FIG. 2) of forty/sixty, the ratio of the first particulate material 20 relative to the second particulate material 22 in the initial thermally conductive filler may be increased to provide for the quantity of the first particulate material 20 to be removed to exclude particles having a size larger than the predetermined particle size. In an embodiment in which the predetermined particle size is set to be the mean particle size of the first particulate material 20, approximately half of the volume of the first particulate material 20 may be removed to exclude particles having a size larger than the predetermined particle size.

For a desired ratio of the first particulate material 20 (shown in FIG. 2) to the second particulate material 22 (also shown in FIG. 2) of forty/sixty in the final thermal interface material, the initial thermally conductive filler may include volume ratio of eighty/sixty to account for the exclusion of approximately half of the volume of the first particulate material 20. The exact ratio of the first particulate material 20 to the second particulate material 22 may vary depending upon the anticipated fraction of the first particulate material 20 and/or the second particulate material 22 to be excluded and the desired ratio of the first particulate material 20 to the second particulate material 22 in the final thermal interface material.

In other alternative embodiments, the thermal interface material may include more than two particulate materials. Each of the particulate materials may have a particle size distribution, e.g., may exhibit generally normally distributed particle sizes, polymodal particle size distribution, etc. The relative particle sizes and ratios of the particulate materials in the final thermal interface material may be selected to provide a desired packing density, or free volume.

In the preferred embodiment, the thermally conductive filler taught by the present invention is suitable for use as a thermal interface material. The first and second particulate materials will therefore include thermally conductive particulate materials. Examples of suitable thermally conductive materials include silver, aluminum, copper, boron nitride, aluminum nitride, silver coated copper, silver coated aluminum, copper coated aluminum, diamond, etc. Various additional thermally conductive materials that will be apparent to one skilled in the art may also be employed. By way of an example, the first particulate material 20 may be copper and the second particulate material 22 may be aluminum.

In addition, the first and second particulate materials 20 and 22 (both shown in FIG. 2) may be made of the same material with differing mean particle sizes and/or particle size distributions, or may instead be made of different materials again with (differing mean particle sizes and/or particle size distributions). The particulate materials contemplated by the present invention may include any suitable particle geometry such as, but not limited to, spherical, elliptical, ellipsoidal, and planar (i.e., flake, irregular, or prismatic). As such, the first particulate material and the second particulate material may have different particles geometries from each another.

A thermal interface material that includes a thermally conductive filler with a controllable packing density or free volume, and has first and second particulate materials having a predetermined maximum size obtained by the exclusion of particles above a predetermined diameter, can be used to provide a relatively low thermal impedance. This low thermal impedance facilitates heat transfer between a relatively hot first interface surface 24 such as a semiconductor chip or a semiconductor package and a relatively cold second interface surface 26 such as an integrated heat spreader or a heat sink.

Generally, thermal impedance is a measure of the total resistance of the flow of heat from a hot surface through an interface material and into a cold surface. As shown in FIG. 4, thermal impedance is proportional to the thickness of the joint, i.e., proportional to the thickness of the thermally conductive filler between a hot first interface surface 24 such as the semiconductor package and a cold second interface surface 26 such as the heat spreader or heat sink. The thermal impedance is also inversely proportional to the thermal conductivity of the thermally conductive filler.

The thermal impedance provided by a thermally conductive filler incorporated into a thermal interface material can thus be reduced by providing a reduction in the bond line thickness (the average thickness of the thermally conductive filler between the relatively hot surface and the relatively cold surface). In part, the bond line thickness is a function of the particle size of the thermally interface material used in the thermal interface material. Thermally conductive filler particles are generally not compressible and/or readily deformable, so the minimum bond line thickness may not generally be less than the size of the largest filler particle. Thus, the thermally conductive filler taught by the present disclosure provides a thin bond line thickness by excluding particles having a size greater than a predetermined size. In the preferred embodiment, the bond line thickness may be one particle in thickness. As mentioned above, a 635 mesh may be used to exclude particles greater than 0.8 mils in size. By so doing, a bond line thickness of 0.8 mils may be achieved by a thermal interface material using the thermally conductive filler described herein.

The mixture of larger particles and smaller particles achieved by using the first and second particulate materials 20 and 22 as the thermally conductive filler provides a relatively large average particle size for a given packing density. The relatively large average particle size will, when combined with a matrix material, provide a lower viscosity as compared to a thermally conductive filler having a smaller average particle size. The lower viscosity facilitates providing a small bond line thickness by allowing the thermal interface material, including the thermally conductive filler and a matrix material, to be squeezed down to a small thickness under a load that is endurable by a semiconductor chip and/or semiconductor package without damage.

Additionally, the thermal impedance provided by a thermal interface material having the thermally conductive filler of the present invention may be reduced by providing an increased thermal conductivity of the matrix material. As discussed above, the thermal impedance of a thermal interface material is inversely proportional to the thermal conductivity of the thermally conductive filler incorporated therein. The thermal conductivity of the thermal interface material is also related to the thermal conductivity of the matrix material, as well as to the volume fraction of the thermally conductive filler and the matrix material.

By including a first particulate material 20 having relatively large particles and a second particulate material 22 having relatively small particles, the relatively small particles of the second particulate material 22 will at least partially fill the interstices of the first particulate material 20, thereby providing an increased packing density of the particles of the thermally conductive filler. Bo so doing, the volume fraction of the thermally conductive filler may be increased relative to the matrix material. The increased volume fraction of the thermally conductive filler relative to the matrix material provided by the increased packing density of the particles of the thermally conductive filler will increase the thermal conductivity of the thermally conductive filler. This increased thermal conductivity of the thermally conductive filler may decrease the thermal impedance provided by the thermal interface material.

In addition to increasing the volume fraction of the thermally conductive filler relative to the less thermally conductive matrix material, the thermal interface material may also provide a relatively higher bulk thermal conductivity as compared to the use of a single particulate material. The thermal interface material of the present invention has a relatively large average particle size for a given thermally conductive filler volume fraction in the thermal interface material, with the relatively larger average particle size of the thermally conductive filler providing a relatively higher bulk thermal conductivity. Accordingly, a thermal interface material including the thermal filler material taught by the present invention provides an increased thermal conductivity resulting from an increased thermally conductive filler volume. fraction as well as from an increased bulk thermal conductivity.

Thus, a thermal interface material utilizing the thermally conductive filler disclosed herein will increase the performance of a thermal management system by decreasing the thermal impedance between components. The thermal impedance is reduced by excluding particles having a diameter above a predetermined diameter, thereby decreasing the bond line thickness. The thermal impedance is also reduced by increasing the thermal conductivity of the thermally conductive filler, which may be achieved by increasing the packing density of the thermally conductive filler in the thermal interface material.

A thermal interface material including the thermally conductive filler disclosed herein may be prepared by combining the thermally conductive filler with various matrix materials and/or additional processing aids, additives, etc. Commonly, the thermal interface material is provided as a thermal grease. In a thermal grease, the thermally conductive filler may be combined with a dispersal agent such as silicone oil, hydrocarbon or mineral oil, petroleum jelly, etc. The thermally conductive filler may be dispersed in the silicone oil, hydrocarbon or mineral oil, and or petroleum jelly to provide a paste, a viscous fluid, or a gel, as desired. The viscosity of the thermal grease is generally inversely proportional to the particle size of the thermal, interface material, but can be influenced by the viscosity of the ingredients of the matrix material.

The exclusion of particles above a predetermined diameter and/or the mixture of the smaller particles of the second particulate material 22 with the larger particles of the first particulate material 20 reduces somewhat the average particle size of the thermally conductive filler. This reduced average particle size may somewhat increase the viscosity of the thermal grease. The increased viscosity of the thermal grease may reduce migration of the thermal grease, and may also reduce the occurrence and/or the rate of “pump out,” in which thermal cycling of the system forces the thermal grease from between the mating surfaces of the thermal management system.

A thermal interface material consistent with the present invention may additionally utilize a binder in the matrix material. The binder may be a rubber, such as a hydrocarbon rubber, e.g., an olefin rubber. Suitable rubbers may include saturated as well as unsaturated rubbers, and may also include crosslinkable and/or non-crosslinkable rubbers. Various other binders may additionally or instead be used. Such other binders may include various polymeric and/or oligomeric materials and/or mixtures thereof. Suitable polymeric and/or oligomeric materials may include both thermoplastic and thermoset polymeric materials including, but not limited to, epoxies, polyurethanes, polyesters, olefins, acrylics, etc.

In addition, a thermal interface material may be provided utilizing the thermally conductive filler taught by the present invention in combination with a phase change material. Generally phase change materials may melt and solidify to store and release heat. Advantageously, suitable phase change materials may have a melting temperature in the operating temperature range of the thermal management system, e.g., between about 40 degrees Centigrade to about 106 degrees Centigrade for use in semiconductor thermal management systems. Examples of phase change materials are waxes, such as paraffin waxes and microcrystalline waxes, polymeric waxes such as polyethylene wax, etc., as well as mixtures thereof.

An optimized thermal interface material may include the thermally conductive filler taught by the present invention together with a combination of two or more matrix materials. For example, the matrix materials may include petroleum or silicon-based oil or gel dispersal agent, a phase change material such as a wax, a coupling agent such as titanate coupling agent, and optionally an antioxidant and/or a binder such as a rubber or an adhesive. Such a combination of matrix materials can provide lower thermal impedance and may resist migration of the thermally conductive filler. Such combinations may, therefore, provide enhanced thermal performance and may also provide a prolonged lifecycle. If both an organic material and an inorganic material is used in the matrix material, it is useful to use a coupling agent such as titanate coupling agent to facilitate a smooth interface between the organic and inorganic materials. Additionally, an antioxidant may also be used to keep wax and/or other materials from oxidizing.

As an example, the matrix material used to bind the first particulate materials 20 and the second particulate material 22 can include a phase change material such as microcrystalline wax or a polyethylene wax, a mixture of a low viscosity spreading agent such as mineral oil or silicone oil and a high viscosity dispersal agent such as petroleum jelly, a coupling agent such as a titanate coupling agent, and an antioxidant. In such a matrix material, microcrystalline wax can be used in an amount of between approximately zero to approximately sixty percent, mineral oil can be used in an amount of approximately zero to approximately 60 percent, petroleum jelly can be used in an amount of approximately zero to approximately thirty percent, titanate coupling agent can be used in an amount of approximately zero to approximately fifteen percent, and an antioxidant can be used in an amount of approximately zero to approximately two percent.

In the preferred embodiment, the microcrystalline wax can be used in an amount of approximately forty percent, mineral oil can be used in an amount of approximately thirty-seven and one-half percent, petroleum jelly can be used in an amount of approximately ten and seven-tenths percent, titanate coupling agent can be used in an amount of approximately ten and seven-tenths percent, and an antioxidant can be used in an amount of approximately one and one-tenth percent. A microcrystalline wax that is suitable is mp 55° C. microcrystalline wax such as the product available from The International Group, Inc. a its IGI 3040. A mineral oil that is suitable is 88 cSt at 40° C. mineral oil such as the product available from STE Oil Company, Inc. as its Crystal Plus 500FG. A petroleum jelly that is suitable is Petrolatum A0101 such as the product available from The Candlewic company. A titanate coupling agent that is suitable is KRTTS from Kenrich Petrochemicals Inc. Finally, an antioxidant that is suitable is Irganox 1076 from Ciba Specialty Chemicals.

By way of example, the thermally conductive filler that is incorporated with the matrix material described above may use copper powder as the first particulate material 20 and aluminum powder as the second particulate material 22. The average particle sizes of the aluminum powder may be approximately 0.08 mills, approximately one-tenth the size of the average particle size of the copper powder which is approximately 0.8 mils, with both the copper and aluminum powders being spherical in nature. In the example given herein, the thermal impedance of the thermal interface material is approximately 0.101° K.-cm²/W. If the thermally conductive filler is put through a 635 mesh to filer out larger particles, while maintaining the relative percentages of the first and second particulate materials 20 and 22, the thermal impedance of the thermal interface material is approximately 0.084° K.-cm²/W, a seventeen percent reduction.

It may therefore be appreciated from the above detailed description of the preferred embodiment of the present invention that it teaches a thermal interface material presenting a particularly low level of thermal impedance. The thermal interface material of the present invention has good viscosity characteristics, specifically a viscosity that is sufficiently low to provide good flow properties when the thermal interface material is in use between two surfaces. The thermal interface material of the present invention uses particles of thermally conductive filler of at least two different sizes to simultaneously present both excellent thermal interface properties and a lower viscosity to provide very good flow properties.

The thermal interface material of the present invention is capable of using any of a plurality of different thermally conductive fillers to provide excellent characteristics at a modest cost. For example, the thermal interface material of the present invention may use multiple different thermally conductive fillers each having different particle sizes. The improved and novel thermally conductive fillers of the thermal interface material of the present invention are packaged in a binder system that provides excellent performance characteristics that both augment the favorable characteristics of the thermally conductive filler and in some embodiments can provide outstanding phase change characteristics.

The thermal interface material of the present invention is of a composition that is stable and will remain so for an extended period of time, maintaining its low thermal impedance and other favorable characteristics throughout the operating lifetime of the electronics with which it is associated. The thermal interface material of the present invention is relatively inexpensive to manufacture to enhance its market appeal and to thereby afford it the broadest possible market. Finally, all of the aforesaid advantages and objectives of the thermal interface material of the present invention are achieved without incurring any substantial relative disadvantage.

Although the foregoing description of the thermally conductive material of the present invention has been shown and described with reference to particular embodiments and applications thereof, it has been presented for purposes of illustration and description and is not intended to be exhaustive or to limit the invention to the particular embodiments and applications disclosed. It will be apparent to those having ordinary skill in the art that a number of changes, modifications, variations, or alterations to the thermally conductive material of the present invention as described herein may be made, none of which depart from the spirit or scope of the present invention. The particular embodiments and applications were chosen and described to provide the best illustration of the principles of the invention and its practical application to thereby enable one of ordinary skill in the art to utilize the invention in various embodiments and with various modifications as are suited to the particular use contemplated. All such changes, modifications, variations, and alterations should therefore be seen as being within the scope of the present invention as determined by the appended claims when interpreted in accordance with the breadth to which they are fairly, legally, and equitably entitled.

What is claimed is:

1. A thermal interface material comprising:
a matrix material; and
a thermally conductive filler comprising a first thermally conductive particulate material having a first particle size distribution and a first mean particle size, and a second thermally conductive particulate material having a second particle size distribution and a second mean particle size, wherein said first mean particle size is larger than said second particle size.

2. A thermal interface material as defined in claim 1, wherein said first mean particle size is between about four to about twenty times said second mean particle size.

3. A thermal interface material, as defined in claim 2, wherein said first mean particle size is about 10 times said second mean particle size.

4. A thermal interface material as defined in claim 1, wherein particles larger than a first size are excluded from said first thermally conductive particulate material.

5. A thermal interface material as defined in claim 1, wherein particles larger than a first size are excluded from said thermally conductive filler.

6. A thermal interface material as defined in claim 1, wherein said first particle size distribution and said second particle size distribution overlap in part.

7. A thermal interface material as defined in claim 1, wherein said first particle size distribution and said second particle size distribution do not overlap.

8. A thermal interface material as defined in claim 1, wherein said first thermally conductive particulate material and said second thermally conductive particulate material are made of the same material.

9. A thermal interface material as defined in claim 1, wherein said first thermally conductive particulate material and said second thermally conductive particulate material are made of different materials.

10. A thermal interface material as defined in claim 1, wherein each of said first and second thermally conductive particulate materials are made of a material from the group consisting of silver, aluminum, copper, boron nitride, aluminum nitride, silver coated copper, silver coated aluminum, copper coated aluminum, and diamond.

11. A thermal interface material as defined in claim 1, wherein said first and second thermally conductive particulate materials are substantially spherical in configuration.

12. A thermal interface material as defined in claim 1, wherein said first and second thermally conductive particulate materials are substantially elliptical in configuration.

13. A thermal interface material as defined in claim 1, wherein said first thermally conductive particulate material is made of copper powder and said second thermally conductive particulate material is made of aluminum powder.

14. A thermal interface material as defined in claim 1, wherein said first thermally conductive particulate material constitutes between about twenty percent and about seventy percent by volume of said thermal interface material, and wherein said second thermally conductive particulate material constitutes between about ten percent and about seventy percent by volume of said thermal interface material.

15. A thermal interface material as defined in claim 14, wherein said first thermally conductive particulate material constitutes about 28.35 percent by volume of said thermal interface material, and wherein said second thermally conductive particulate material constitutes about 43.65 percent by volume of said thermal interface material.

16. A thermal interface material as defined in claim 1, wherein said matrix material comprises a phase change material.

17. A thermal interface material as defined in claim 16, wherein said phase change material comprises a wax.

18. A thermal interface material as defined in claim 17, wherein said phase change material comprises microcrystalline wax.

19. A thermal interface material as defined in claim 1, wherein said matrix material comprises a spreading agent.

20. A thermal interface material as defined in claim 19, wherein said spreading agent comprises at least one of the group consisting of mineral oil, silicone oil, and petroleum jelly.

21. A thermal interface material as defined in claim 20, wherein said spreading agent comprises a mixture of mineral oil and petroleum jelly to provide a suitable viscosity.

22. A thermal interface material as defined in claim 1, wherein said matrix material comprises a coupling agent.

23. A thermal interface material as defined in claim 22, wherein said coupling agent comprises a titanate coupling agent.

24. A thermal interface material as defined in claim 1, wherein said matrix material comprises an antioxidant.

25. A thermal interface material as defined in claim 1, wherein said matrix material comprises a binder.

26. A thermal interface material as defined in claim 25, wherein said binder comprises a rubber.

27. A thermal interface material as defined in claim 25, wherein said binder comprises a polymeric or oligomeric material.

28. A thermal interface material as defined in claim 27, wherein said polymeric or oligomeric material comprises an epoxy or acrylate material.

29. A thermal interface material comprising:
a matrix material comprising a phase change material, a spreading agent, a coupling agent, and an antioxidant; and
a thermally conductive filler comprising a first thermally conductive particulate material having a first particle size distribution, and a second thermally conductive particulate material having a second particle size distribution, particles larger than a first size being excluded from said filler.

30. A thermal interface material comprising:
a matrix material; and
a thermally conductive filler comprising a first thermally conductive particulate material having a first particle size distribution, and a second thermally conductive particulate material having a second particle size distribution different from said first particle size distribution.

31. A thermally conductive filler comprising:
a first thermally conductive particulate material having a first particle size distribution and a first mean particle size; and
a second thermally conductive material having a second particle size distribution and a second mean particle size, wherein said first mean particle size is larger than said second particle size.

32. A thermally conductive filler as defined in claim 31, wherein said particles larger than a first size are excluded from said first thermally conductive particulate material.

33. A thermally conductive filler as defined in claim 31, wherein said first thermally conductive particulate material comprises a first mean particle size and said second thermally conductive material comprises a second mean particle size, said first mean particle size being between about four to about twenty times said second mean particle size.

34. A thermally conductive filler as defined in claim 31, wherein said first thermally conductive particulate material comprises a first mean particle size and said second thermally conductive material comprises a second mean particle size, said first mean particle size being about 10 times said second mean particle size.

35. A thermally conductive filler as defined in claim 31, wherein said first thermally conductive particulate material comprises copper.

36. A thermally conductive filler as defined in claim 31, wherein said second thermally conductive particulate material comprises aluminum.

37. A method for producing a thermally conductive filler comprising:
providing a first thermally conductive particulate material having a first particle size distribution and a first mean particle size;
providing a second thermally conductive particulate material having a second particle size distribution and a second mean particle size, wherein said first mean particle size is larger than said second particle size; and
combining said first and second thermally conductive particulate materials.

38. A method as defined in claim 37, additionally comprising:
excluding a fraction of said first thermally conductive particulate material having a particle size greater than a predetermined particle size.

39. A method as defined in claim 37, wherein said first thermally conductive particulate material has a first mean particle size and said second thermally conductive particulate material has a second mean particle size, said first mean particle size being between about four to about twenty times said second mean particle size.

40. A method as defined in claim 37, wherein said first thermally conductive particulate material has a first mean particle size and said second thermally conductive particulate material has a second mean particle size, said first mean particle size being about 10 times said second mean particle size.

41. A method as defined in claim 37, further comprising combining said first and second thermally conductive particulate materials with a matrix.

42. A method as defined in claim 41, wherein said matrix comprises a phase change material.

43. A method as defined in claim 41, wherein said matrix comprises a polymeric or oligomeric material.

44. A method as defined in claim 41, wherein said matrix comprises a rubber.

45. A method as defined in claim 37, wherein excluding said fraction of said first thermally conductive particulate material comprises screening said first thermally conductive particulate material.
